(19) United States
(12) Patent Application Publication
(10) Pub. No.: US 2026/0103604 A1
(43) Pub. Date: Apr. 16, 2026

(54) LAMINATE CONTAINING AN ADHESION PROMOTER LAYER AND METHOD OF MAKING THE LAMINATE

(71) Applicant: CANON KABUSHIKI KAISHA, Tokyo (JP)

(72) Inventors: Fen WAN, Austin, TX (US); Weijun Liu, Cedar Park, TX (US); Amy R. Klohn, Austin, TX (US); Toshiki Ito, Kawasaki-shi (JP)

(21) Appl. No.: 18/917,142

(22) Filed: Oct. 16, 2024

(51) Int. Cl. C09D 5/00; C09D 4/00; C09D 7/63; C09D 125/16

(52) U.S. Cl. CPC C09D 5/002; C09D 4/00; C09D 7/63; C09D 125/16

(57) ABSTRACT

A laminate can comprise a substrate, an adhesion promoter layer, and a coating layer, wherein the adhesion promoter layer may include a silane compound of formula (1): Xₘ—Si—Yₙ (1), wherein X is at least one of OR, NR₂, or SR, or a combination thereof, with R being substituted or unsubstituted alkyl or aryl; Y is CH═CH₂ or L-CH═CH₂, with L being phenyl or C₁-C₅ alkyl; m is 1-3, n is 1-3, with m+n=4. The adhesion promoter layer can provide strong adhesion of the coating layer to the substrate by forming covalent bonds with the substrate and covalent bonds with the coating layer.

### FIELD OF THE DISCLOSURE

The present disclosure relates to a laminate containing a substrate, an adhesion promoter layer, and a coating layer, and a method of making the laminate, the adhesion promoter layer includes a silane compound.

### BACKGROUND

UV-curable materials in the field of inkjet adaptive planarization (IAP) can include vinylbenzene-based polymerizable materials for forming cured resist layers having a high etch resistance and high thermal stability. However, one disadvantage of such cured resist layers is a weak adhesion to the underlying substrate.

There exists a need to improve the adhesion strength of resist layers formed from curable vinylbenzene-based monomer compositions to the underlying substrate, particularly in IAP processing.

### SUMMARY

In one embodiment, a laminate can comprise a substrate; an adhesion promoter layer directly overlying the substrate, the adhesion promoter layer including a silane compound of formula (1): Xₘ—Si—Yₙ (1), wherein X is at least one of OR, NR₂, or SR, or a combination thereof, with R being alkyl or aryl; Y is CH═CH₂ or L-CH═CH₂, with L being phenyl or C₁-C₅alkyl; m is 1-3, n is 1-3, with m+n=4; and a coating layer directly overlying the adhesion primer layer.

In one aspect of the laminate, X of formula (1) of the silane compound can be O—R, wherein R is C₁-C₃ alkyl; Y is CH═CH₂ or phenyl-CH═CH₂, m is 1-3, n is 1-3, and m+n=4.

In certain aspects of the laminate, the silane compound of formula (1) can include

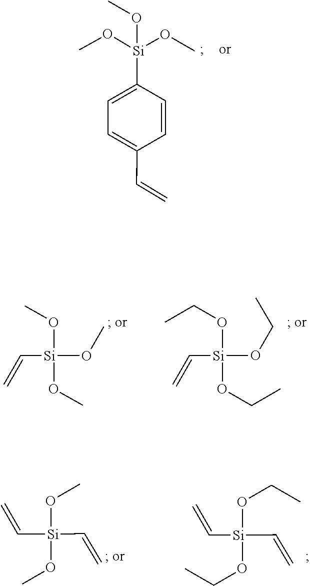

or any combination thereof.

In particular certain aspects, the silane compound can include

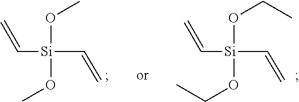

or a combination thereof.

In another particular certain aspect, the silane compound can include

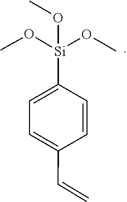

In one aspect of the laminate, the material of the substrate can comprise silicon, aluminum, zirconium, tin, titanium, and nickel.

In another aspect of the laminate, the thickness of the adhesion promoter layer can be at least 0.5 nm and not greater than 100 nm.

In a further aspect of the laminate, the amount of the silane compound of formula (1) in the adhesion promoter layer can be at least 90 wt % based on the total weight of the adhesion promoter layer.

In one embodiment of the laminate, the coating layer can be a cured resist of a multi-functional vinylbenzene-based IAP material. In one aspect, the vinylbenzene-based IAP material can be a photocurable composition comprising at least 80 wt % of a multi-functional vinylbenzene monomer based on the total weight of the polymerizable material. In a certain particular aspect, the multi-functional vinylbenzene-based IAP material can be essentially free of acrylate monomers.

In another aspect of the laminate, the vapor pressure of the silane compound can be at least 0.08 Torr at 25° C.

In another embodiment, a method of forming a laminate can comprise: applying an adhesion promoter layer directly on an outer surface of a substrate, wherein the adhesion promoter layer can comprise a silane compound of formula (1): Xₘ—Si—Yₙ (1), wherein X is at least one of OR, NR₂, or SR, with R being alkyl or aryl; Y is —CH═CH₂ or L-CH═CH₂, with L being phenyl or C₁-C₅ alkyl; m is 1-3, n is 1-3, with m+n=4; and applying a coating layer directly overlying the adhesion promoter layer.

In one aspect of the method, applying the adhesion promoter layer can comprise vapor depositing the silane compound on the outer surface of the substrate.

In another aspect, the method can include forming of covalent bonds between the adhesion promoter layer and the substrate, and forming of covalent bonds between the adhesion promoter layer and the coating layer.

In yet a further aspect of the method, applying the coating layer can include applying a liquid photocurable composition on the adhesion promoter layer and curing the curable composition to form the coating layer. In a particular aspect, the curable composition can comprise a polymerizable material including at least 80 wt % of at least one multi-functional vinylbenzene monomer based on the total weight of the polymerizable material.

In a further aspect of the method, the vapor pressure of the silane compound can be at least 0.08 Torr at 25° C.

In particular aspects of the method, the silane compound of formula (1) can include

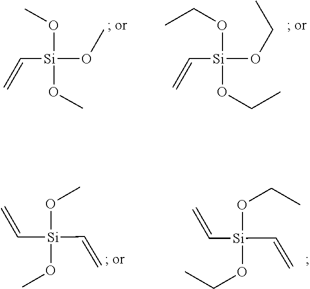

or any combination thereof.

In another embodiment, a method of manufacturing an article can comprise: applying a layer of a curable composition on a substrate, wherein the substrate may comprise an adhesion promoter layer including a silane compound of formula (1): Xₘ—Si—Yₙ, (1), wherein X is at least one of OR, NR₂, or SR, or a combination thereof, with R being alkyl or aryl; Y is CH═CH₂ or L-CH═CH₂, with L being phenyl or C₁-C₅ alkyl: m is 1-3, n is 1-3, with m+n=4, and wherein the curable composition comprises a polymerizable material including at least 80 wt % of at least one multi-functional vinylbenzene monomer based on the total weight of the polymerizable material; bringing the curable composition into contact with a superstrate; irradiating the curable composition with light to form a cured layer; removing the superstrate from the cured layer to obtain a laminate; and manufacturing the article from the laminate.

### BRIEF DESCRIPTION OF THE DRAWINGS

Embodiments are illustrated by way of example and are not limited in the accompanying figures.

FIG. 1A includes an illustration of a laminate according to one embodiment.

FIG. 1B includes an illustration of an assembly for testing the adhesion strength of the coating layer to the substrate of the laminate of FIG. 1A according to one embodiment.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

As used herein, the terms “alkyl” group or “aryl” are used to encompass groups having no substituents (e.g., an unsubstituted alkyl group) but can also include substituted groups (e.g., a substituted alkyl group or a substituted aromatic ring).

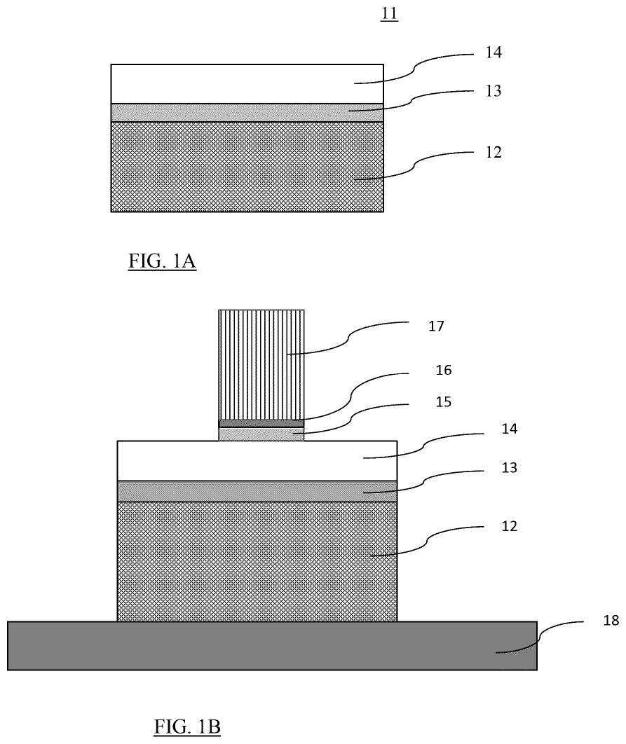

In one embodiment, as illustrated in FIG. 1A, the present disclosure is directed to a laminate (11) comprising a substrate (12), an adhesion promoter layer (13) directly overlying the substrate (12), and a coating layer (14) directly overlying the adhesion promoter layer (13). The adhesion promoter layer (13) can include a silane compound of formula (1): Xₘ—Si—Yₙ, (1), wherein X is at least one of OR, NR₂, or SR, or a combination thereof, with R being alkyl or aryl; Y is CH═CH₂ or L-CH═CH₂, with L being phenyl or C₁-C₅alkyl; in is 1-3, n is 1-3, with m+n=4. As shown in embodiments herein, the adhesion promoter layer of the laminate can assist in an excellent adhesion of the coating layer to the substrate.

In one aspect, X of formula (I) can be O—R, with R being C₁-C₃ alkyl, Y can be CH═CH₂ or phenyl-CH═CH₂, m can be 1-3, n may be 1-3, and m+n can be 4.

In a certain aspect, the silane compound of formula (1) can be a small molecule having a molecular weight not greater than 1000 g/mol, not greater than 500 g/mol, not greater than 400 g/mol, not greater than 300 g/mol, or not greater than 200 g/mol.

In one aspect, the silane compound of formula (1) can comprise at least two alkoxy-groups directly attached to the and at least one vinyl group or phenylvinyl group directly attached to the Si.

In another aspect, the silane compound can comprise two alkoxy groups (for example, methoxy or ethoxy groups) directly attached to the Si and two vinyl groups directly attached to the Si.

In a particular aspect, the silane compound of formula (1) can include:

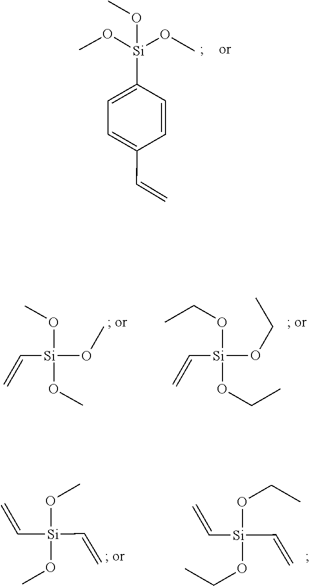

or any combination thereof.

In a certain particular aspect, the silane compound can include

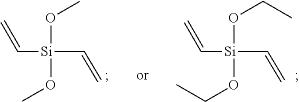

or a combination thereof.

In another certain particular aspect, the silane compound may include

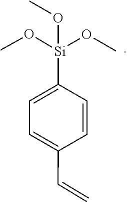

In one aspect, the silane compound of formula (1) of the adhesion promoter layer (13) can form covalent bonds with the substrate (12) and covalent bonds with the coating layer (14). In a certain aspect, the XR group of the silane compound of formula (1) can form covalent bonds with functional groups of the substrate, for example, with hydroxyl groups being present on the surface of the substrate. In another certain aspect, the vinyl groups of the silane compound may form covalent bonds with vinyl groups of vinylmonomers contained in the coating composition during curing.

As used herein, the phrase “silane compound of formula (1)” is interchangeable used with the term “adhesion promoter,” if not indicated otherwise.

As used herein, the term “laminate” is called interchangeable “coated substrate” or “multi-layer structure,” if not indicated otherwise.

In one embodiment, a method of forming the laminate (11) of the present disclosure can include: i) applying an adhesion promoter layer (13) directly on a substrate (12); and ii) applying a coating layer (14) directly on the adhesion promoter layer (13).

The substrate (12) of the laminate (11) can be a material selected from a metal, a metal alloy, a ceramic, a glass, or a polymer. In aspects, the substrate can comprise silicon, aluminum, zirconium, tin, titanium, or nickel, or their oxides. In a particular aspect, the substrate can be a silicon wafer. Not being bound to theory, functional groups contained in the outer surface region of the substrate can react by forming covalent bonds with functional groups of the adhesion promoter of formula (1).

In one particular aspect, the adhesion promoter layer can be applied on the substrate by vapor deposition. The vapor deposition can be adapted that only a single layer of molecules of the adhesion promoter is deposited on the substrate. In another aspect, the adhesion promoter layer can contain a plurality of adhesion promoter molecules along a thickness direction of the layer.

In a certain aspect, the silane compound of formula (1) can partially undergo self-cross-linking during or after vapor deposition and before applying the coating layer.

Vapor deposition can be conducted by using a bubbler, or a vaporizer, or manually. The bubbler and the vaporizer can use an inert gas, typically nitrogen, to cause the adhesion promoter to be vaporized, and the vapor is blown in a closed chamber containing a substrate (e.g., a Si wafer) on which the adhesion promoter is deposited. After a certain given time, the wafer can have sufficient deposited adhesion promoter deposited on its surface and may be used for TAP processing. In comparison to spin coating, the vaporization can be easily integrated into an automated TAP process, which can increase the throughput.

In the aspect of manual vaporization, as used herein, a defined amount of the adhesion promoter is added to an open container, e.g., a petri dish, and placed together with the substrate (e.g., a silicon wafer) in a closed vessel, such as a desiccator or a Wafer Foup. Depending on the vapor pressure of the adhesion promoter and the applied vacuum, the adhesion promoter will vaporize in the closed vessel in a defined period of time and deposit on the substrate.

In certain aspects the vapor pressure of the silane compound of formula (1) can be at least 0.08 Torr at 25° C., or at least 0.1 Torr, or at least 0.15 Torr, or at least 0.2 Torr, or at least 0.5 Torr, or at least 1 Torr, or at least 5 Torr, or at least 10 Torr. In another aspect, the vapor pressure of the silane compound of formula (1) may be not greater than 100 Torr, or not greater than 80 Torr, or not greater than 50 Torr.

In another particular aspect, the adhesion promoter layer can be applied by immersing the substrate in a liquid adhesion promoter, or in a solution containing the adhesion promoter dissolved in a solvent, thereby allowing the adhesion promoter to be adsorbed on the substrate surface.

In other aspects, the adhesion promoter layer can be also applied on the substrate by spin-coating, spraying, or brushing.

In a further aspect, the thickness of the adhesion promoter layer can be at least 0.4 nm, such as at least 0.5 nm, at least 0.7 nm, at least 1 nm, at least 2 nm, at least 3 nm, or at least 5 nm. In another aspect, the thickness of the adhesion promoter layer can be not greater than 15 nm, such as not greater than 10 nm, not greater than 5 nm. The thickness of the adhesion promoter layer can be a value between any of the minimum and maximum values noted above, such from 0.4 nm to 15 nm, or from 0.6 nm to 5 nm.

In one aspect, the amount of the adhesion promoter in the adhesion promoter layer can be at least 50 wt % based on the total weight of the adhesion promoter layer, or at least 80 wt %, or at least 90 wt %, or at least 95 wt %, or at least 98 wt %, or at least 99 wt %, or at least 99.5 wt %, or at least 99.9 wt %. In a particular aspect, the adhesion promoter layer can consist essentially of the adhesion promoter, except for unavoidable impurities.

In one embodiment, the coating layer (14) can be a cured resist formed by curing a curable composition. As used herein, if not indicated otherwise, the term curable composition relates to the curable composition for forming the coating layer (14) of the laminate (11).

In one aspect, the curable composition can comprise a polymerizable material which may form a polymeric network if initiated to polymerization by light and/or heat.

In one aspect, the polymerizable material of the curable composition may include at least one multi-functional vinylbenzene monomer. As used herein, the term multi-functional vinylbenzene monomer of the polymerizable material relates to a polymerizable monomer comprising one or more benzene rings and at least two vinyl groups directly attached to the one or more benzene rings. In certain aspects, the multi-functional vinylbenzene monomer can comprise at least three vinyl groups or at least four vinyl groups. In a particular aspect, the multi-functional vinylbenzene monomer can comprise two benzene rings and three vinyl groups attached to the benzene rings. A non-limiting example of such monomer can be 3,4′,5-trivinyl-1,1′biphenyl (3VPH).

In a particular aspect the polymerizable material of the curable composition can comprise at least 80 wt % of a multi-functional vinylbenzene monomer based on the total weight of the polymerizable material, or at least 85 wt %, or at least 95 wt %, or at least 98 wt %. In another aspect 100% of the polymerizable material can be at least one multi-functional vinylbenzene monomer, or not greater than 97 wt %, or not greater than 95 wt %, or not greater than 90 wt %.

In a certain aspect, the polymerizable material can comprise up to 20 wt % polymerizable monomers which are different than multi-functional vinylbenzene monomers.

In one aspect, the polymerizable material of the coating composition can comprise an acrylate monomer in an amount of at least 1 wt % to not greater than 20 wt %, or at least 2 wt % and not greater than 15 wt %, or not greater than 10 wt %, or not greater than 5 wt %. In a particular aspect, the polymerizable material of the curable coating composition can be essentially free of acrylate monomers. As used herein, essentially free of acrylate monomer means that the amount of acrylate monomers is not greater than 1 wt % based on the total weight of the polymerizable material.

The amount of polymerizable material contained in the curable composition can be at least 40 wt % based on the total weight of the curable composition, or at least 60 wt %, or at least 70 wt %, or at least 80 wt %, or at least 90 wt %, or at least 95 wt %. In another aspect, the amount of polymerizable material may be not greater than 99 wt %, or not greater than 96 wt %, or not greater than 92 wt % based on the total weight of the curable composition.

In a further aspect, the curable composition can contain a solvent which is not polymerizable and can be removed by drying before and/or during the polymerization. In another certain aspect, the curable composition can be essentially free of a solvent. As used herein, essentially free of a solvent means that an amount of the solvent in the curable composition is less than 5 wt % based on the total weight of the curable composition.

In another aspect, the curable composition can be free of particles as required for IAP processing.

In one embodiment, the viscosity of the curable composition at 23° C. can be at least 1.0 mPa·s, at least 5 mPa·s, at least 10 mPa·s, at least 15 mPa·s, at least 20 mPa·s, or at least 30 mPa·s. In another embodiment, the viscosity may be not greater than 100 mPa·s, such as not greater than 70 mPa·s, not greater than 50 rmPa·s, not greater than 40 mPa·s, or not greater than 30 mPa·s. The viscosity of the curable composition can be a value between any of the minimum and maximum values noted above. All viscosities recited herein are viscosities measured with the Brookfield method, using a Brookfield Viscometer LVDV-II+Pro at 200 rpm, with a spindle size #18 and a spin speed of 135 rpm.

In yet a further aspect, the curable composition of the resist can contain at least one additive. Non-limiting examples of an additive can be a surfactant, a dispersant, a stabilizer, a co-solvent, an initiator, an inhibitor, or any combination thereof.

In a particular embodiment, the coating layer of the laminate can be an imprint resist layer attached to a wafer substrate by the adhesion promoter layer and adapted for a nanolithographic process.

The contact angle of a liquid resist to the applied surface is an important parameter in nanoimprinting, since it affects the drop spreading of the IAP resist and the further performance during processing. As a general rule can be applied that the smaller the contact angle the faster the drop spreading. In one aspect, the contact angle of a defined curable IAP composition (hereinafter also called “IAP test resist”) dropped on the adhesion promoter layer of the present disclosure can be not greater than 30 degrees, such as not greater than 25 degrees, or not greater than 20 degrees. In another aspect, the IAP contact angle may be at least 2 degrees, or at least 10 degrees, or at least 15 degrees. The exact composition of the IAP test resist and the measurement of the contact angle is described in the experimental section below.

In another embodiment, the thickness of the coating layer after curing can be at least 10 nm micron, or at least 50 nm, or at least 100 nm. In another aspect, the thickness of the coating layer may be not greater than 1000 nm, or not greater than 500 nm, or not greater than 100 nm, or not greater than 50 nm.

In one aspect, the adhesion strength (herein also called pull-off strength) of the coating layer to the substrate at 23° C. can be at least 2.5 Mpa, such as at least 3.0 MPa, or at least 3.5 MPa, or at least 4.0 MPa, or at least 4.5 MPa, or at least 5.0 MPa, of at least 5.5 MPa, or at least 6.0 MPa, or at least 6.5 MPa, such as at least 7.0 MPa, at least 7.5 MPa, at least 8.0 MPa, or at least 8.5 MPa. In another aspect, the adhesion strength may be not greater than 20 MPa, such as not greater than 15 MPa, or not greater than 10 MPa.

In a further embodiment, the present disclosure is directed to a method of attaching a coating layer (e.g., an IAP resist layer) to a substrate. The method can comprise the following steps: applying the adhesion promoter layer described above on a surface of a substrate; applying a layer of a liquid curable composition directly on top of the adhesion promoter layer; and curing the curable composition.

In a particular embodiment, the curable composition can be applied to the substrate containing the adhesion promoter layer by ink-jetting. Depending on the material of the curable composition, curing can be conducted by UV radiation, heat treatment, or a combination thereof.

In another embodiment, the present disclosure is directed to a method of forming a cured planarized layer. The method can comprise forming an adhesion promoter layer as described above on a substrate. Thereafter, a curable composition (for example, a liquid imprint resist) can be applied on top of the adhesion promoter layer and a superstrate may be brought in contact with the curable composition such that the curable composition forms a planar layer. Thereafter, the curable composition can be cured by radiation with light, for example, UV light, or via heat treatment, to form a cured planar layer. After curing of the curable composition, the superstrate can be removed from the cured layer, leaving a flattened resist on the substrate. As used herein, the term “planar layer” or “cured layer” are interchangeable used with the term “coating layer.”

The laminate comprising the cured planar layer may be used as an interlayer insulating film of a semiconductor device, such as LSI, system LSI, DRAM, SDRAM, RDRAM, or D-RDRAM, or as a resist film used in a semiconductor manufacturing process.

As further demonstrated in the examples, it has been surprisingly found that an adhesion promoter having the structure of formula (1) can provide good adhesion of a coating layer to a substrate, wherein the coating layer is formed by a curable composition containing to a large amount multi-functional vinylbenzene monomers. The laminate of the present disclosure can be very suitable for IAP processing.

### EXAMPLES

The following non-limiting examples illustrate the concepts as described herein.

### Example 1

Forming of laminate having the structure of: silicon wafer/adhesion promoter layer/coating layer (IAP resist).

A silicon wafer with a diameter of 12 inches and a thickness of 750 microns was cut into four quarters.

Thereafter, the wafer was placed within a small vacuum desiccator having a diameter of 150 mm (from Kimlet). In the vacuum desiccator was placed at the bottom within a petri dish 0.5 g of the adhesion promoter. The vacuum desiccator was closed with its lid and the silicon wafer was maintained for 1 hour within the desiccator at standard air pressure and room temperature (no vacuum applied) to allow vapor deposition of the adhesion promoter on the silicon wafer.

As adhesion promoters representative to the present disclosure were used: p-styryl-trimethoxysilane (sample S1), vinyltrimethoxysilane (sample S2), and triethoxyvinylsilane (sample S3). Furthermore, the following three comparative adhesion promoters were used for making laminates: vinylmethyldimethoxysilane (comparative sample C1), and vinylmethyldiethoxysilane (comparative sample C2), and vinyldimethylethoxysilane (comparative sample C3). See exact structures and summary in Table 1.

Table 1

| | | Vapor | Adhesion | Adhesion | IAP |
|---|---|---|---|---|---|
| | | Pressure at | strength | strength | Contact |
| | Adhesion Promoter | 25° C. [Torr] | [Lbf] | [MPa] | Angle [°] |
| S1 | 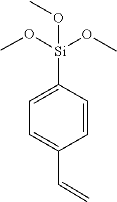 | 0.0893 | 37 | 8.4 | 18.3 |
| S2 | 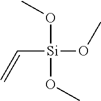 | 16.4 | 12 | 2.7 | 22.1 |
| S3 | 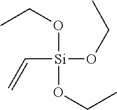 | 3.09 | 15 | 3.4 | 15.9 |
| C1 | 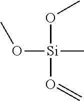 | 92 | 19 | 4.3 | 30.2 |
| C2 | 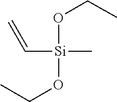 | 10.6 | 17 | 3.8 | 28.9 |
| C3 | 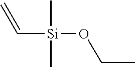 | 44.8 | 8.5 | 1.9 | 39 |

After vapor depositing the adhesion promoter layer, the wafer was cut to a size of 2 inches×1 inch and a liquid photocurable resist composition, herein called TAP test resist, was applied on top of the adhesion promoter layer by dispensing with a pipette three drops of the LAP test resist, each drop having a volume of three microliters. The LAP test resist composition contained 100 parts of 3,5,3′-Vinyldiphenylmethane, 1.5 parts photoinitiator Irgacure 1316, 4 parts photoinitiator Irgacure 651, and 3 parts surfactant SA3070 from Aoki Oil Industrial Co., Ltd.

Thereafter, on top of the dispensed TAP test resist was placed a glass slide coated with Cytop (from AGC Chemicals Americas, Inc.), wherein the Cytop coated side of the glass slide was facing the LAP test resist.

The IAP test resist contained in the stack was cured with UV radiation having a wavelength of 365 nm, using a total radiation energy of 30 mJ/cm² to form a solid IAP resist layer. After the curing and removing the glass slide, a laminate was obtained with the layer structure silicon wafer/adhesion promoter layer/IAP resist layer, wherein the thickness of the cured IAP resist layer was about 200 microns.

For the testing of the adhesion strength of the cured IAP resist layer to the silicon substrate, which is herein also called interchangeable pull-off strength, the force needed to pull-off the IAP layer (14) from the substrate (12) via an adhesively connected glass rod (17) was measured.

Specifically, as illustrated in FIG. 1B, the following setup for the adhesion test was prepared:

A glass rod (17) (Technical Glass Products, WE 214 fused quartz rod) having the size of 5 mm diameter×12 mm length was adhesively attached to the IAP layer (14) of the laminate (11). For attaching the glass rod to the IPA layer, the glass rod was coated on one end with an adhesion primer (herein called also just primer) using a cotton swab and baked at a temperature of 180° C. to obtain a firm adhesion between the primer and the rod. The adhesion primer contained 81 g IsoRad 501 (an aromatic polyacrylate from Schenectady International, Inc. in Schenectady, New York), 18 g Cymel 303ULF (comprising as a main ingredient hexamethoxymethyl-melamine (HMMM)), and 1 g of a catalyst (Cycat 4040). Thereafter, the primer coated end of the glass rod (16) was adhesively attached to the laminate by coating it with a NIL resist, and placing the rod with the NIL-resist coated end (15) at the center of the cured outer IAP layer (14) of the laminate (11). The NIL resist was cured with UV radiation of 365 nm and a light intensity of 290 mW/cm² for 10 minutes, which caused the glass rod to be adhesively attached to the laminate. The NIL resist was selected to ensure that the adhesive strength of the glass rod (17) to the IAP layer (14) via the cured NIL (15) was greater than the adhesive strength of the IAP layer (14) to the silicon wafer (12) via the adhesion promoter layer (13). The exact composition of the NIL resist was: 10 wt % isobornyl acrylate, 35 wt % benzyl acrylate, 50 wt % neopentyl glycol diacrylate; 3 wt % Darocur 4265 (from BASF); and 2 wt % TPO (from BASF).

Thereafter, the laminate containing the attached glass rod was glued with the backside (silicon wafer side) to an aluminum plate (18) having a size of (1 inch×25 inches×⅛ inch) using an epoxy adhesive (Gorilla Epoxy Adhesive Clear from Gorilla Glue Company). The epoxy adhesive was selected to insure that the adhesion strength of the aluminum plate to the silicon wafer was stronger than the adhesion strength of the photo-cured resist layer to the silicon wafer.

The actual adhesion test (measuring the pull-off strength) was conducted by measuring the force needed to pull-off the TAP layer (14) from the substrate via the adhesively attached glass rod (17), using an Instron Model 5542 Tensile Tester.

For the testing, the above-described laminate attached to the aluminum plate (18) via the silicon wafer (12) and containing the glass rod (17) anchored with one end to the IAP layer (14) of the laminate via the photo-cured NIL resist (15) was placed in a fixed position in the Tensile Tester. A moving head from the Instron tensile tester was adjusted that it moved at a speed of 0.5 mm per minute towards the glass rod and hit the glass rod at its side, at a position 5.3-5.4 mm away from the end of the glass rod attached to the resist. The force was recorded at which the glass rod with the attached IAP resist layer (14) was separated from the silicon substrate (12). The adhesion strength (i.e., pull-off strength of the TAP resist to the silicon wafer) was measured in pounds per force (lbf) and normalized to lbf/mm² by dividing by the surface area of 19.62 mm² of the glass rod end. The normalized lbf/mm² value was further converted to the unit MPa by multiplication with the factor 4.4482. An illustration of the layered assembly containing the laminate of FIG. 1A is shown in FIG. 1B.

For each sample, the testing was repeated eight times and an average value of the pull-off-strength was calculated.

The results of the adhesive strength measurements are summarized in Table 1. It can be seen that a high adhesion strength, combined with a low TAP resist contact angle is obtained for samples S1, S2, and S3, while comparative samples C1, C2, and C3 either had a much lower adhesion strength of less than 2 MPa (see comparative sample C3) or a higher TAP resist contact angles of greater than 28 degrees (see comparative samples C1 and C2). High TAP contact angles are not desired since it negatively influences the drop spreading behavior of the TAP resist.

### Measurement of the IAP Contact Angle to Adhesion Promoter Layer:

The IAP contact angles were measured with a Drop Master DM-701 contact angle meter made by Kyowa Interface Science Co. Ltd. (Japan).

For the testing, 2 ml of the IAP test resist (see description above) was added to the syringe, of which 2 μl sample per test was added by the machine to the surface of the silicon wafer coated with the adhesion promoter layer. Drop images were continuously captured by a CCD camera from the time the resist drop touched the layer surface. The contact angle was automatically calculated by the software based on the analysis of the images. The IAP contact angles presented in Table 1 are the contact angles at a time of 3 seconds after the IAP resist drop was touching the surface of the adhesion promoter layer.

### Example 2

Surface Free Energy of adhesion promoter layers.

The surface free energy (SFE) was measured for the adhesion promoter layers of samples S1, S2, and S3, as well as for the primer-coated glass rod and the bare silicon wafer.

The SFE measurements were also measured with the Drop master DM-701 described above, by measuring in a first measurement the contact angle of water and in a second measurement the contact angle of diiodomethane to the target surface (the surface of the adhesion promoter layer). The surface free energy was calculated based on both contact angle values using the Owens-Wendt method with the analysis software FAMAS installed in the Drop Mater DM-701 instrument.

The results of the measurements are summarized in Table 2. It can be seen that the adhesion promoter layers of samples S1, S2, and S3 were in a range between 40 and 50 mJ/cm², and similar to the primer coating with 48.2 mJ/cm². In contrast, the bare silicon wafer, without adhesion promoter layer, had a much higher SFE of 73.6 mJ/cm².

Not being bound to theory, it is assumed that the low SFE of the adhesion promoter layers, and the low IAP contact angles (see Table 4 and Table 1) are due to the fact that the same type of functional group, i.e., vinyl groups, were contained in both the adhesion promoter layer and the IAP resist. Because of the low SFE, when IAP resist drops land on the adhesion promoter layer, the drops will stay at the placing location until being subjected to pressure by the superstrate. In contrast, on the bare silicon wafer surface, the drops can easily deform and/or dislocate, which may result in filling defects.

TABLE 2

| Sample | SFE [mJ/m²] |
|---|---|
| S1 | 49.9 |
| S2 | 41 |
| S3 | 42 |
| Primer-coated glass rod | 48.2 |
| Bare Si | 73.6 |

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A laminate comprising:
a substrate;
an adhesion promoter layer directly overlying the substrate, the adhesion promoter layer including a silane compound of formula (1):
Xₘ—Si—Yₙ, (1),
wherein X is at least one of OR, NR₂, or SR, or a combination thereof, with R being alkyl or aryl; Y is CH═CH₂ or L-CH═CH₂, with L being phenyl or C₁-C₅ alkyl; m is 1-3, n is 1-3, with m+n=4; and
a coating layer directly overlying the adhesion primer layer.

2. The laminate of claim 1, wherein X of formula (1) is O—R, with R being C₁-C₃ alkyl; Y is CH═CH₂ or phenyl-CH═CH₂, m is 1-3, n is 1-3, and m+n=4.

3. The laminate of claim 2, wherein the silane compound of formula (1) is selected from 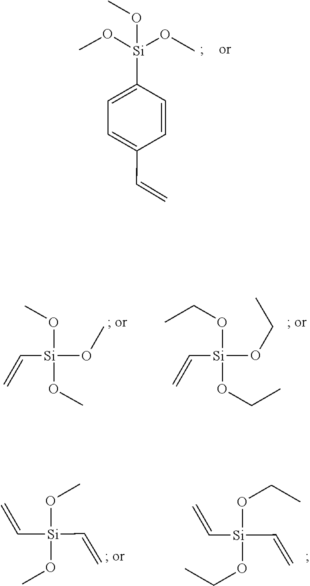
or any combination thereof.

4. The laminate of claim 3, wherein the silane compound includes 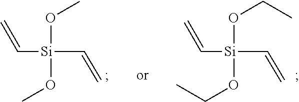
or a combination thereof.

5. The laminate of claim 3, wherein the silane compound includes

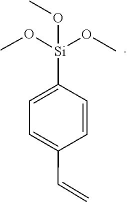

6. The laminate of claim 1, wherein a material of the substrate comprises silicon, aluminum, zirconium, tin, titanium, and nickel.

7. The laminate of claim 1, wherein a thickness of the adhesion promoter layer is at least 0.5 nm and not greater than 100 nm.

8. The laminate of claim 1, wherein an amount of the silane compound of formula (1) in the adhesion promoter layer is at least 90 wt % based on the total weight of the adhesion promoter layer.

9. The laminate of claim 1, wherein the coating layer is a cured resist of a multi-functional vinylbenzene based IAP material.

10. The laminate of claim 9, wherein the vinylbenzene based IAP material is a photocurable composition comprising at least 80 wt % of a multi-functional vinylbenzene monomer based on the total weight of the polymerizable material.

11. The laminate of claim 10, wherein the multi-functional vinylbenzene based IAP material is essentially free of acrylate monomers.

12. The laminate of claim 1, wherein a vapor pressure of the silane compound is at least 0.08 Torr at 25° C.

13. A method of forming a laminate, comprising:
applying an adhesion promoter layer directly on an outer surface of a substrate,
wherein the adhesion promoter layer comprises a silane compound of formula (1): Xₘ—Si—Yₙ(1), wherein X is at least one of OR, NR₂, or SR, with R being alkyl or aryl; Y is —CH═CH₂ or L-CH═CH₂, with L being phenyl or C₁-C₅ alkyl; m is 1-3, n is 1-3, with m+n=4; and
applying a coating layer directly overlying the adhesion promoter layer.

14. The method of claim 13, wherein applying the adhesion promoter layer comprises vapor depositing the silane compound on the outer surface of the substrate.

15. The method of claim 13, wherein the method includes forming of covalent bonds between the adhesion promoter layer and the substrate, and forming of covalent bonds between the adhesion promoter layer and the coating layer.

16. The method of claim 13, wherein applying the coating layer includes applying a liquid photocurable composition on the adhesion promoter layer and curing the photocurable composition to form the coating layer.

17. The method of claim 16, wherein the liquid photocurable composition comprises a polymerizable material including at least 80 wt % of at least one multi-functional vinylbenzene monomer based on the total weight of the polymerizable material.

18. The method of claim 13, wherein a water vapor pressure of the silane compound is at least 0.08 Torr at 25° C.

19. The method of claim 13, wherein the silane compound of formula (1) is selected from 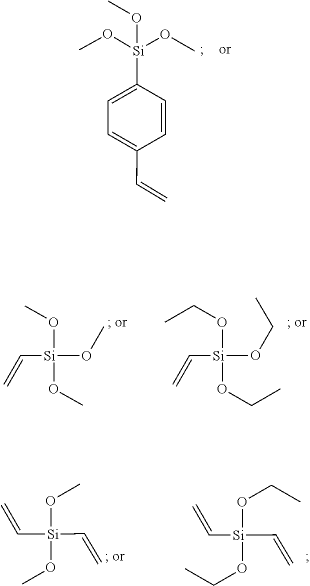
or any combination thereof.

20. A method of manufacturing an article, comprising:
applying a layer of a curable composition on a substrate, wherein the substrate comprises an adhesion promoter layer including a silane compound of formula (1): Xₘ—Si—Yₙ, (1), wherein X is at least one of OR, NR₂, or SR, or a combination thereof, with R being alkyl or aryl; Y is CH═CH₂ or L-CH═CH₂, with L being phenyl or C₁-C₅ alkyl; m is 1-3, n is 1-3, with m+n=4, and wherein the curable composition comprises a polymerizable material including at least 80 wt % of at least one multi-functional vinylbenzene monomer based on the total weight of the polymerizable material;
bringing the curable composition into contact with a superstrate;
irradiating the curable composition with light to form a cured layer;
removing the superstrate from the cured layer to obtain a laminate; and
manufacturing the article from the laminate.
